(19) United States
(12) Patent Application Publication
(10) Pub. No.: US 2022/0076971 A1
(43) Pub. Date: Mar. 10, 2022

(54) SELF ALIGNING WAFER CARRIER PEDESTAL ELEMENT WITH POWER CONTACTS

(71) Applicant: Applied Materials, Inc., Santa Clara, CA (US)

(72) Inventors: Kirankumar Neelasandra SAVANDAIAH, Bangalore (IN); Nitin Bharadwaj SATYAVOLU, Kakinada (IN); Kaushik VAIDYA, Bangalore (IN); Bhaskar PRASAD, Adityapur (IN); Srinivasa Rao YEDLA, Bangalore (IN); Aju PHILIP, Bangalore (IN); Thomas BREZOCZKY, Los Gatos, CA (US)

(21) Appl. No.: 17/013,339

(22) Filed: Sep. 4, 2020

(51) Int. Cl. H01L 21/67; H01L 21/677; H01L 21/68

(52) U.S. Cl. CPC H01L 21/67196; H01L 21/67167; H01L 21/68; H01L 21/67742; H01L 21/67745; H01L 21/6719

(57) ABSTRACT

Embodiments disclosed herein relate to an apparatus for aligning and securing a transferable substrate support. In one embodiment, a substrate support assembly includes a transferable substrate support. The transferable substrate support includes one or more first separable contact terminals disposed on a surface of the transferable substrate support. Each of the first separable contact terminals includes a detachable connection region and an electrical connection region, and the electrical connection region is coupled to an electrical element disposed within the transferable substrate support. The detachable connection region of each of the one or more first separable contact terminals is configured to detachably connect and disconnect with a corresponding pin of one or more pins of a supporting pedestal by repositioning the supporting pedestal relative to the transferable substrate support in a first direction.

### BACKGROUND

### Field

Embodiments of the present disclosure generally relate to apparatuses, systems and methods for processing semiconductor substrates. More specifically, the embodiments disclosed herein relate to a self-aligning substrate support assembly and pedestal that is useful while processing a substrate in a processing system.

### Description of the Related Art

In semiconductor wafer processing equipment, substrate supports are used for retaining wafers during processing. The wafer rests on a susceptor, for example an electrostatic chuck. Electrostatic chucks (or chuck) secure a substrate by creating an electrostatic attractive force between the substrate and the chuck. A voltage applied to one or more insulated electrodes in the chuck induces opposite polarity charges in the surface of the substrate and substrate supporting surface of the chuck, respectively. The opposite charges generate a “chucking force” which causes the substrate to be pulled onto or attracted to the substrate supporting surface of the chuck, thereby retaining the substrate. To ensure secure attachment, the substrate must be properly aligned with the chuck. If the substrate is misaligned, the substrate may become dislodged from the surface of the chuck, become misaligned with the substrate supporting surface of the chuck and/or move undesirably during processing.

To ensure secure attachment, the substrate support must be properly aligned within a processing chamber. If the substrate support is not aligned within the processing chamber, the deposition or etching process results (e.g., film thickness) will be skewed due to the misalignment of the chuck and the substrate to the rest of the chamber. If the chuck and the substrate support are misaligned, the chuck may become dislodged from the substrate support during a translational movement and/or move undesirably during processing. Furthermore, the substrate support assembly must be functional in high-temperature, vacuum environments, which are common in substrate processing operations.

Thus, there is a need for a self-aligning substrate support assembly and pedestal operable in high-temperature, vacuum environments.

### SUMMARY

Embodiments disclosed herein relate to an apparatus for aligning and securing a transferable substrate support. In one embodiment, a substrate support assembly includes a transferable substrate support. The transferable substrate support includes one or more first separable contact terminals disposed on a surface of the transferable substrate support. Each of the first separable contact terminals includes a detachable connection region and an electrical connection region, and the electrical connection region is coupled to an electrical element disposed within the transferable substrate support. The detachable connection region of each of the one or more first separable contact terminals is configured to detachably connect and disconnect with a corresponding pin of one or more pins of a supporting pedestal by repositioning the supporting pedestal relative to the transferable substrate support in a first direction.

In another embodiment, an assembly includes a transferable substrate support, one or more first separable contact terminals disposed on a surface of the transferable substrate support, a supporting pedestal, and one or more pins disposed on the supporting pedestal. Each of the one or more pins is configured to detachably connect and disconnect with a corresponding terminal of the one or more first separable contact terminals.

In yet another embodiment, a transferable substrate support includes a plurality of separable contact terminals disposed on a surface of the transferable substrate support. The plurality of separable contact terminals include three radii intersecting a center point of the transferable substrate support. Each radius is disposed at an angle of 60 and/or 120 degrees with respect to each of the other radii. The plurality of separable contact terminals includes one or more first separable contact terminals, the one or more first separable contact terminals including two terminals located on each of the three radii. The plurality of separable contact terminals further includes one or more second separable contact terminals, the one or more second separable contact terminals including two terminals located at locations on the transferable substrate support other than on the three radii.

In yet another embodiment, a transferable substrate support, comprises a plurality of separable contact terminals disposed on a surface of the transferable substrate support. The plurality of separable contact terminals comprising two first separable contact terminals located on each of three radii, wherein the three radii intersect a center point of the transferable substrate support, each radius being disposed at an angle with respect to each of the other radii, and one or more second separable contact terminals located at locations on the transferable substrate support other than on the three radii.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1 illustrates a plan view of a cluster tool assembly according to one or more embodiments.

FIGS. 2A-2B illustrate schematic cross-sectional views of a transfer chamber assembly and a processing assembly according to one or more embodiments.

FIG. 3A illustrates a perspective view of a transferable substrate support according to one or more embodiments.

FIG. 3B illustrates a perspective view of a pedestal according to one or more embodiments.

FIG. 3C illustrates a perspective view of a pedestal according to one or more additional embodiments.

FIG. 4 illustrates a top view of the transferable substrate support of FIG. 3A.

FIG. 5 illustrates a side view of the alignment of the second separable contact pins with the first separable contact terminals.

FIGS. 6A-6B illustrate a detail view of the alignment of the first separable contact pins and/or second separable contact pins with the first separable contact terminals of FIG. 5.

FIGS. 7A-7B illustrate a detail view of the alignment of the second separable contact pins with the second separable contact terminals according to one or more additional embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the present disclosure include an apparatus and methods for processing one or more substrates in a processing system. Electrostatic chucks are used as substrate supports to develop an electrostatic force that holds substrates in place in various processing areas of the processing system. In some embodiments, the substrate support assembly includes contact terminals which separably connect to corresponding pins of a pedestal. These connections self-align the electrostatic chuck within the processing chamber while providing an electrical contact for generating electrostatic force and/or delivering power to one or more resistive heating elements disposed within chuck. This assembly improves alignment of the electrostatic chuck and the substrate during processing as well as efficiency of processing operations. Furthermore, the shapes of the separable contact terminals and pins are capable of passing high voltage and high current at high processing temperatures in a vacuum environment.

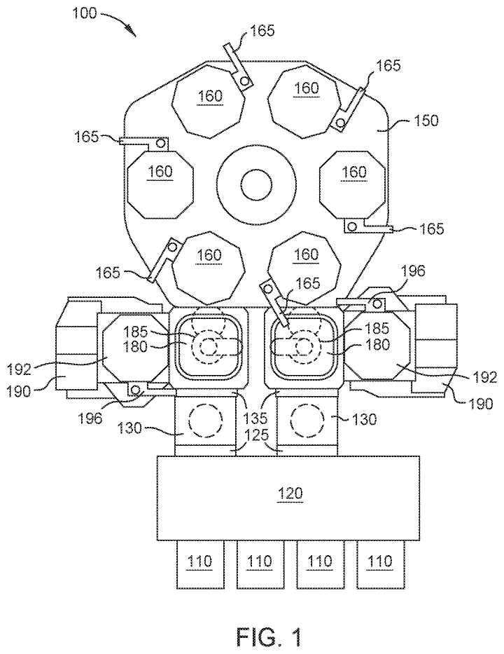

FIG. 1 is a plan view of a processing system, or cluster tool assembly 100, that includes a transfer chamber assembly 150 and processing assemblies 160 as described herein. The cluster tool assembly 100 of FIG. 1 includes a single transfer chamber assembly 150 and a plurality of front end robot chambers 180 between the transfer chamber assembly 150 and load lock chambers 130.

In FIG. 1, the cluster tool assembly 100 includes Front Opening Unified Pods (FOUPs) 110, a Factory Interface (FI) 120 adjacent to and operably connected to the FOUPs 110, load lock chambers 130 adjacent to and operably connected to the FI 120, front end robot chambers 180 adjacent to and operatively connected to the load lock chambers 130, prep chambers 190 adjacent to and operatively connected to the front end robot chambers 180, and a transfer chamber assembly 150 connected to the front end robot chambers 180.

The FOUPs 110 are utilized to safely secure and store substrates during movement thereof between different substrate processing equipment, as well as during the connection of the FOUPs to the substrate processing equipment while the substrates are disposed therein. The number of FOUPs 110 (four shown) may vary in quantity depending upon the processes run in the cluster tool assembly 100. The throughput of the cluster tool assembly 100 also, at least in part, defines the number of docking stations on the FI 120 to which the FOUPs are connected for the unloading of substrates therefrom and the loading of substrates thereinto. The FI 120 is disposed between the FOUPs 110 and the load lock chambers 130. The FI 120 creates an interface between a semiconductor fabrication facility (Fab) and the cluster tool assembly 100. The FI 120 is connected to the load lock chambers 130, such that substrates are transferred from the FI 120 to the load lock chambers 130 and from the load lock chambers 130 and into the FI 120.

The front end robot chambers 180 are located on the same side of each of the load lock chambers 130, such that the load lock chambers 130 are located between the FI 120 and the front end robot chambers 180. The front end robot chambers 180 each include a transfer robot 185 therein. The transfer robot 185 is any robot suitable to transfer one or more substrates from one chamber to another, through or via the front end robot chamber 180. In some embodiments, as shown in FIG. 1, the transfer robot 185 within each front end robot chamber 180 is configured to transport substrates from one of the load lock chambers 130 and into one of the prep chambers 190.

The prep chambers 190 may be any one of a pre-clean chamber, an anneal chamber, or a cool down chamber, depending upon the desired process within the cluster tool assembly 100. In some embodiments, the prep chambers 190 are plasma clean chambers. In yet other exemplary embodiments, the prep chambers 190 are Preclean II chambers available from Applied Materials, Inc., of Santa Clara, Calif. A vacuum pump 196 is positioned adjacent to each of the prep chambers 190. The vacuum pumps 196 are configured to pump the prep chambers 190 to a predetermined pressure. In some embodiments, the vacuum pump 196 is configured to decrease the pressure of the prep chamber 190, such as to create a vacuum within the prep chamber 190.

As shown in FIG. 1, two load lock chambers 130, two front end robot chambers 180, and two prep chambers 190 are configured within the cluster tool assembly 100. The two load lock chambers 130, the two front end robot chambers 180, and the two prep chambers 190, when arranged as shown in FIG. 1 and described above, may form two transport assemblies. The two transport assemblies may be spaced from each other and may form mirror images of one another, such that the prep chambers 190 are on opposite walls of their respective front end robot chambers 180.

The transfer chamber assembly 150 is adjacent to, and operatively connected to, the front end robot chambers 180, such that substrates are transferred between the transfer chamber assembly 150 and front end robot chambers 180. The transfer chamber assembly 150 includes a central transfer device 145 and a plurality of processing assemblies 160 therein. The plurality of processing assemblies 160 are disposed around the central transfer device 145, radially outward of a pivot or central axis of the central transfer device 145 in the transfer chamber assembly 150.

A chamber pump 165 is disposed adjacent to, and in fluid communication with, each of the processing assemblies 160, such that there are a plurality of chamber pumps 165 disposed around the central transfer device 145. The plurality of chamber pumps 165 are disposed radially outward of the central transfer device 145 in the transfer chamber assembly 150. As shown in FIG. 1, one chamber pump 165 is fluidly coupled to each of the processing assemblies 160.

In some embodiments, there may be multiple chamber pumps 165 fluidly coupled to each processing assembly 160. In yet other embodiments, one or more of the processing assemblies 160 may not have a chamber pump 165 directly fluidly coupled thereto. In some embodiments a varying number of chamber pumps 165 are fluidly coupled to each processing assembly 160, such that one or more processing assemblies 160 may have a different number of chamber pumps 165 than one or more other processing assemblies 160. The chamber pumps 165 enable separate vacuum pumping of processing regions within each processing assembly 160, and thus the pressure within each of the processing assemblies may be maintained separately from one another and separately from the pressure present in the transfer chamber assembly 150.

FIG. 1 depicts an embodiment having six processing assemblies 160 within the transfer chamber assembly 150. However, other embodiments may have a different number of processing assemblies 160 within the transfer chamber assembly 150. For example, in some embodiments, two to twelve processing assemblies 160 may be positioned within the transfer chamber assembly 150, such as four to eight processing assemblies 160. In other embodiments, four processing assemblies 160 may be positioned within the transfer chamber assembly 150. The number of processing assemblies 160 impact the total footprint of the cluster tool assembly 100, the number of possible process steps capable of being performed by the cluster tool assembly 100, the total fabrication cost of the cluster tool assembly 100, and the throughput of the cluster tool assembly 100.

Each of the processing assemblies 160 can be any one of physical vapor deposition (PVD), chemical vapor deposition (CVD), atomic layer deposition (ALD), etch, cleaning, heating, and/or annealing processing assemblies. In some embodiments, the processing assemblies 160 are all one type of processing assembly. In other embodiments, the processing assemblies 160 includes two or more different processing assemblies. In one exemplary embodiment, all of the processing assemblies 160 are PVD process chambers. In another exemplary embodiment, the processing assemblies 160 includes both PVD and CVD process chambers. The plurality of processing assemblies 160 can be altered to match the types of process chambers needed to complete a semiconductor fabrication process.

The central transfer device 145 is disposed at generally the center of the transfer chamber assembly 150. The central transfer device 145, is any suitable transfer device configured to transport substrates between each of the processing assemblies 160. In one embodiment, the central transfer device 145 is a central robot having one or more blades configured to transport substrates between each processing assembly 160. In another embodiment, the central transfer device is a carousel system by which processing regions are moved along a circular orbital path.

### Processing Module Configuration

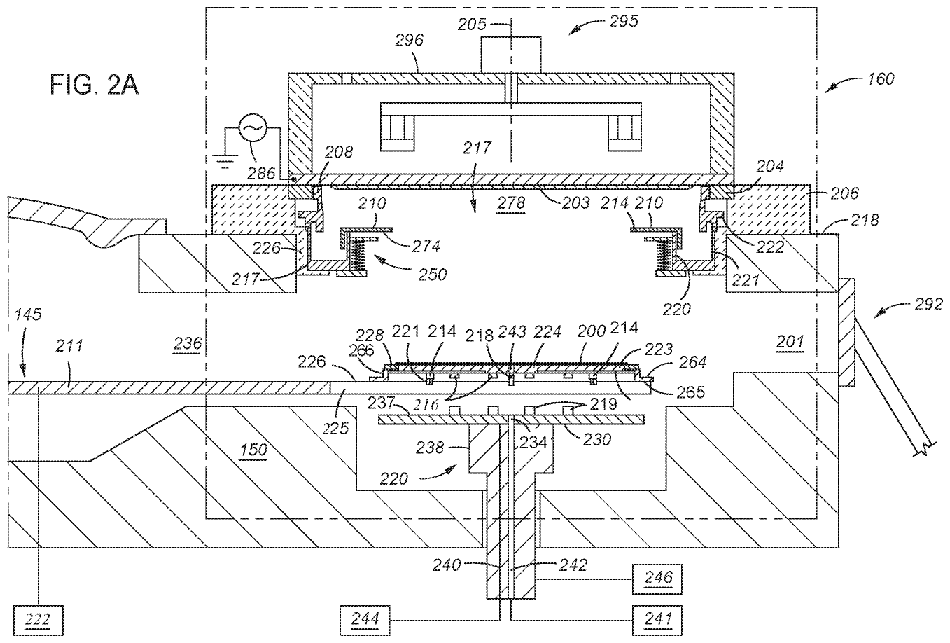

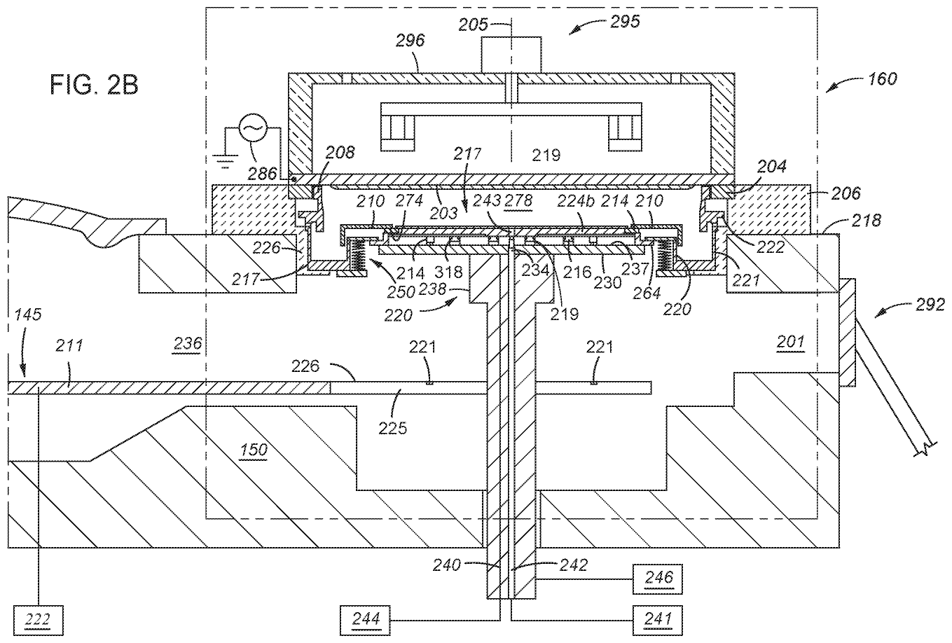

FIGS. 2A-2B are schematic cross sectional views of a portion of the transfer chamber assembly 150 and one of the processing assemblies 160 according to one embodiment. FIGS. 2A-2B depict a magnetron assembly 295, an AC power source 286, an opening 201, a plate and seal assembly 292, a transfer chamber volume 236, a transfer chamber assembly 150, a mini process chamber 217, a transferable substrate support 224 (e.g., electrostatic chuck), and a substrate lift assembly 220. The opening 201 is sized to allow the substrate 200, the transferable substrate support 224, or both the substrate 200 and the transferable substrate support 224 to pass therethrough, such that the substrate 200 may be moved throughout the cluster tool 100 on the transferable substrate support 224.

The processing assembly 160 includes the mini process chamber 217 the magnetron assembly 295, a portion of a transfer chamber volume 236, a portion of the transfer chamber assembly 150, the transferable substrate support 224, and the substrate lift assembly 220. The mini process chamber 217 of FIGS. 2A-2B includes a sputtering target assembly 203, a dielectric isolator 204, a liner 206, a containment member 208, a cover ring 210, the magnetron assembly 295, and a lid member 296. Inside of the mini process chamber 217 is a chamber volume 278.

In FIG. 2A, the transferable substrate support 224 and the lift assembly 220 are shown in a substrate receiving position. While in the substrate receiving position, the transferable substrate support 224 and a substrate 200 disposed on the substrate supporting surface 223 of the transferable substrate support 224 are separate from the lift assembly 220 and can be transported through the transfer chamber assembly 150 by use of the transport arm 211 of the central transfer device 145. The central transfer device 145 moves the substrate 200 and the transferable substrate support 224 in an orbital path to transfer the substrate 200 positioned atop the transferable substrate support 224 to one or more of the processing assemblies 160.

The lift assembly 220 has an upper lift section 230 that is configured to engage with and support the transferable substrate support 224 when it is positioned in a processing position (FIG. 2B). The lift assembly 220 includes a lift assembly shaft 238, an electrical line 240, a backside gas outlet 243, and a gas line 242.

During processing and during transferring operations, performed by the central transfer device 145, the substrate 200 is disposed on the substrate supporting surface 223 of the transferable substrate support 224 while the substrate 200 is positioned within the transfer chamber assembly 150. The transferable substrate support 224 is disposed over the lift assembly 220 when the transferable substrate support 224 is supported by the transport arm 211, and the transport arm is oriented within the processing assembly 160. An edge ring 228 is disposed on the transferable substrate support 224 at a peripheral edge of the substrate 200. A stepped sealing ring 264 is positioned about the periphery of transferable substrate support 224. The transferable substrate support 224 supports the substrate 200 and the edge ring 228. The transferable substrate support 224 includes an electrostatic chuck, such that the transferable substrate support 224 can be biased by an electrical power source, such as a first portion of a power source 244 (e.g., high voltage DC power supply). The biasing of the transferable substrate support 224 chucks the substrate 200 and holds the substrate 200 in place on the transferable substrate support 224 during substrate processing operations and during movement of the lift assembly 220. The transferable substrate support 224 may also contain heating elements (not shown) and thermal sensors (not shown). The heating elements may be connected to a second portion of the power source 244 (e.g., AC power supply) that is used to assist in maintaining a uniform and controlled temperature across the substrate supporting surface 223 and the substrate 200 disposed thereon.

The lift assembly 220 is connected to an actuator 246, for example one or more linear motors or ball-screw servo motor assemblies. The actuator 246 enables vertical movement of the transferable substrate support 224, such that the transferable substrate support 224 can move vertically upwards and downwards through the transfer chamber volume 236, and in some cases rotationally about the central axis 205 in order to align the transferable substrate support 224 for processing and/or transport.

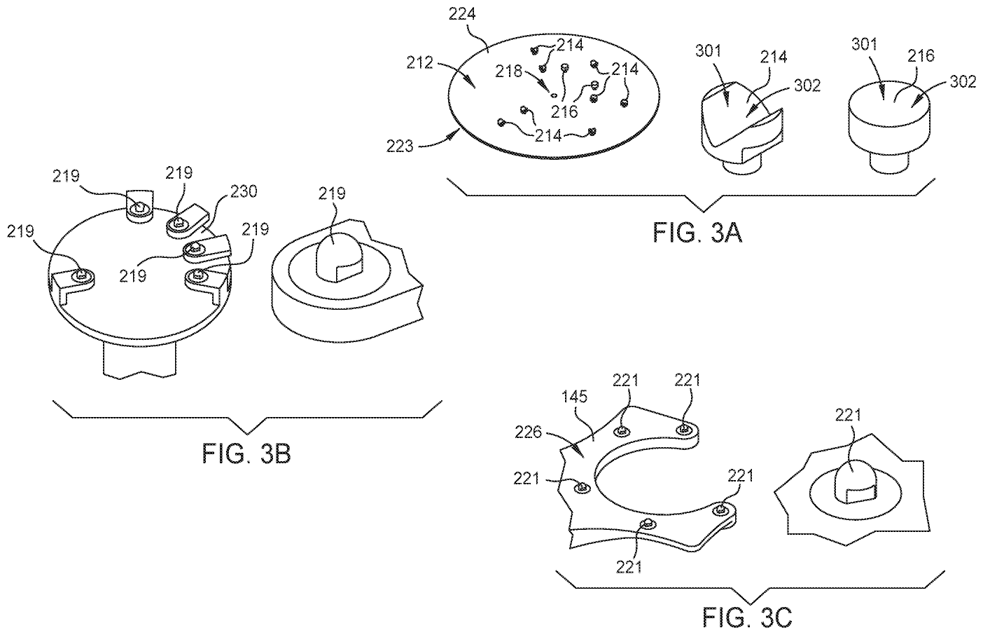

The transferable substrate support 224 further includes a lower surface 212 (FIGS. 2A and 3A). The lower surface 212 is opposite the substrate supporting surface 223 and is, in some cases, parallel to the substrate supporting surface 223. The lower surface 212 includes one or more first separable contact terminals 214, one or more second separable contact terminals 216, and a backside gas connection 218. The first separable contact terminals 214 are disposed on the lower surface 212 and serve as connection points between the transferable substrate support 224 and one or more first separable contact pins 221 disposed on the central transfer device 145. The first separable contact terminals 214 serve to both electrically and physically connect the transferable substrate support 224 to a transport arm 211 of the central transfer device 145. The first separable contact terminals 214 provide power to the transferable substrate support 224 while the transferable substrate support 224 is disposed on the central transfer device 145. The first separable contact terminals 214 also serve to fasten the transferable substrate support 224 to the central transfer device 145 during transfer within the transfer chamber assembly 150, such as from one processing assembly 160 to another processing assembly 160. In some embodiments, there are a plurality of first separable contact terminals 214, such as 2 to 5 first separable contact terminals 214.

The backside gas connection 218 is in fluid communication with the backside gas outlet 243. The backside gas connection 218 and the backside gas outlet 243 are centered in the transferable substrate support 224, such that the backside gas connection 218 and the backside gas outlet 243 are disposed through the center of the transferable substrate support 224. The backside gas connection 218 is connected to and disposed from the bottom side of the backside gas outlet 243, such that the backside gas connection 218 is disposed below the lower surface 212 of the transferable substrate support 224.

As illustrated in FIGS. 2B and 3C, the central transfer device 145 includes a top surface 226, first separable contact pins 221, and a device opening 225. The first separable contact pins 221 are disposed on the top surface 226 of the central transfer device 145 and surrounding the device opening 225. The first separable contact pins 221 are configured to align with the first separable contact terminals 214 on the transferable substrate support 224. In some embodiments, there are a plurality of first separable contact pins 221, such as 2 to 5 first separable contact pins 221. The first separable contact pins 221 (e.g., two of five separable contact pins 221 shown in FIG. 3C) are electrically connected to a first portion of a transfer device power source 222. The first portion of the transfer device power source 222 provides power (e.g., high voltage DC power) for the chucking of the substrate 200 to the transferable substrate support 224 during transportation of the transferable substrate support 224 and the substrate 200 through the transfer chamber assembly 150. The chucking of the substrate 200 during transportation of the transferable substrate support 224 holds the substrate 200 in place on the substrate supporting surface 223 and prevents backside damage to the substrate 200. Some of the first separable contact pins 221 (e.g., three of five separable contact pins 221 shown in FIG. 3C) may also be electrically connected to a second portion of the transfer device power source 222. The second portion of the transfer device power source 222 may be adapted to provide power (e.g., AC power) to one or more resistive heating elements disposed in the transferable substrate support 224 during transportation of the transferable substrate support 224 and the substrate 200 through the transfer chamber assembly 150.

The backside gas connection 218 and the second separable contact terminals 216 are not connected to the central transfer device 145 and are disposed above the device opening 225 (FIG. 2B) while the transferable substrate support 224 is disposed on top of the central transfer device 145, such that the backside gas connection 218 and the second separable contact terminals 216 are disposed radially inward of the first separable contact pins 221 with respect to the processing assembly central axis 205.

In FIG. 2B, the transferable substrate support 224 is disposed on top of the lift assembly 220, such that the transferable substrate support 224 is disposed on top of the upper lift section 230. The upper lift section 230 is disposed on top of and surrounding the lift assembly shaft 238. The lift assembly shaft 238 is a vertical shaft. The lift assembly shaft 238 includes the electrical line 240 and the gas line 242 disposed therein. The electrical line 240 may include multiple electrical conductors, such as wires. The electrical line 240 is used to connect the transferable substrate support 224 to the power source 244. The electrical line 240 and the power source 244 supply power to the transferable substrate support 224 for electrostatic biasing and heating. The power source 244 may also supply power to the actuator 246 for movement of the lift assembly 220.

The gas line 242 is connected to a purge gas source 241. The gas line 242 is in fluid communication with the backside gas outlet 243 through the backside gas connection 218. The backside gas connection 218 connects to the lift assembly 220 through a gas connection receiver 234. The gas connection receiver 234 is disposed on a top surface 237 of the upper lift section 230. Once the backside gas connection 218 couples to the gas connection receiver 234, the purge gas source 241 is in fluid communication with the backside gas outlet 243. The purge gas supplied to the gas line 242 by the purge gas source 241 flows through the backside gas outlet 243 and provides backside gas to the bottom of the substrate 200 disposed on the substrate supporting surface 223.

The lift assembly 220 further includes one or more second separable contact pins 219. The second separable contact pins 219 are disposed on the top surface 237 of the upper lift section 230 of the lift assembly 220. The second separable contact pins 219 are electrically connected to the power source 244 by the electrical line 240. The second separable contact pins 219 supply power to the electrical components found in the transferable substrate support 224 when the transferable substrate support 224 is disposed on the second separable contact pins 219 and the second separable contact terminals 216 of the lift assembly 220. The second separable contact pins 219 and the second separable contact terminals 216 couple to one another when the lift assembly 220 is raised from the lower receiving position up to the central transfer device 145 and passes through the device opening 225 to contact the second separable contact terminals 216. The transferable substrate support 224 is then separated from the central transfer device 145 as the lift assembly 220 is raised through the device opening 225 and moves to a processing position as shown in FIG. 2B.

When the transferable substrate support 224 is connected to the lift assembly 220, such as when the lift assembly 220 is raised to the process position, the second separable contact terminals 216 and the second separable contact pins 219 are coupled together, and in some configurations the backside gas connection 218 is coupled to the gas connection receiver 234.

The stepped sealing ring 264 is disposed radially outward of and connected to the transferable substrate support 224 with respect to the processing assembly central axis 205. The stepped sealing ring 264 is disposed below and has an overlapping annular surface area that is configured to mate with the bellows assembly 250, such that the stepped sealing ring 264 contacts and forms a seal with the bellows assembly 250 when the transferable substrate support 224 and the lift assembly 220 are raised to be in an upper processing position, such as in FIG. 2B. While the transferable substrate support 224 is disposed on the central transfer device 145, the stepped sealing ring 264 may be positioned above the top surface 226 of the central transfer device 145. In some alternate embodiments, the stepped sealing ring 264 supports at least part of the weight of the transferable substrate support 224 and supports the transferable substrate support 224 during transportation of the transferable substrate support 224 and the substrate 200 throughout the transfer chamber assembly 150 and while the lift assembly 220 is in the lower transfer position.

In some embodiments, lift pins (not shown) may be disposed in lift pin holes formed through the transferable substrate support 224, and the upper lift section 230 of the lift assembly 220. The lift pins may extend to the substrate supporting surface 223. The lift pins are configured to lift and lower the substrate 200 between processing steps or when substrates are loaded or unloaded from the transfer chamber assembly 150. In some embodiments, other substrate transfer mechanisms are used in place of the lift pins. In this configuration, the lift pins are omitted to reduce leakage of process gas between the transfer chamber volume 236 and the chamber volume 278 during substrate processing. In embodiments such as those disclosed herein, the transferable substrate support 224 as well as the substrate 200 are transferred in and out of the transfer chamber volume 236 using a robot with similar chucking capabilities as the central transfer device 145. In some embodiments, lift pins are formed to lift at least part of the transferable substrate support 224 from the lift assembly 220 along with the substrate 200. The central transfer device 145 remains disposed at the location of the processing assembly 160 during the processing of the substrate 200 in the chamber volume 278. In some embodiments, the central transfer device 145 is a carousel device and transports a plurality of substrates 200 between the processing assemblies 160 of the transfer chamber assembly 150. The central transfer device 145 is configured to remain in a lower transfer position during the vertical movement of the lift assembly 220 and during substrate 200 processing, such that the central transfer device 145 remains still while the transferable substrate support 224 and the substrate 200 are vertically transported to the processing position and during substrate processing.

The embodiments of FIG. 2A-2B allow for removal of the transferable substrate support 224 from the substrate lift assembly 220. The transferable substrate support 224 is coupled to an arm of the central transfer device 145 during transportation of the substrate 200 and the transferable substrate support 224 between processing assemblies 160. Coupling the transferable substrate support 224 to the central transfer device 145 along with the substrate 200 decreases wear on the top surface of the transferable substrate support 224 and enables the transferable substrate support 224 to be utilized for a greater amount of time before replacement or maintenance of the transferable substrate support 224. By keeping the substrate 200 on the transferable substrate support 224, it has also been found that backside damages to the substrate 200 may be reduced as the substrate 200 is being lifted from and deposited onto the transferable substrate support 224 at a lower frequency than conventional designs that include a stationary substrate support that is associated with a particular processing assembly.

### Support Chuck Structure Example

FIG. 3A illustrates a perspective view of a backside surface 212 of a transferable substrate support 224 according to one or more embodiments. The transferable substrate support 224 includes one or more first separable contact terminals 214 and one or more second separable contact terminals 216 disposed on the surface 212 of the transferable substrate support 224. Each of the first separable contact terminals 214 and the second separable contact terminals 216 includes a detachable connection region 301 and an electrical connection region 302. The electrical connection region 302 is coupled to an electrical element (e.g., chucking electrode, resistive heating element) disposed within the transferable substrate support 224. The electrical connection region 302 is operable in a vacuum environment, for example from about 10⁻³ to about 10⁻⁸ Torr, and at high temperatures, for example up to 550° C. Additionally, the electrical connection region 302 is operable at high currents, for example up to 30 A, and at high voltages, for example up to 1500 VDC. For example, the electrical connection region 302 may be operated in a vacuum environment of about 10⁻⁵ to about 10⁻⁸ Torr, at a temperature of about 450° C. to about 550° C., at a current of about 20 A to about 30 A, and at a voltage of about 1000 VDC to about 1500 VDC. It is believed that the particular pressure, temperature, current, and voltage at which the electrical connection region 302 is operable is at least a result of the configurations and materials used to fabricate the first separable contact terminals 214 and the second separable contact terminals 216. While traditional substrate supports may have difficulty functioning at these processing conditions, the transferable substrate support 224 described herein is able to function at relatively low pressures and at relatively high temperatures, currents, and voltages. In one example, repeatable electrical contact formation issues in traditional substrate support designs may be attributed to phenomena, such as cold welding that are common when two clean, similar metals strongly adhere when brought into contact in a vacuum environment.

In one embodiment, which can be combined with other embodiments disclosed herein, one or more of the first separable contact terminals 214 have a contact surface that is concave. In one example, as illustrated in FIG. 5, the first separable contact terminals 214 are concave and are facing in a −Z-direction. In one embodiment, which can be combined with other embodiments disclosed herein, one or more of the first separable contact terminals 214 includes a contact surface that is a flat surface that is disposed parallel to the surface 212 of the transferable substrate support 224. In one embodiment, which can be combined with other embodiments disclosed herein, one or more of the second separable contact terminals 216 includes a contact surface that is a flat surface that is disposed parallel to the surface 212 of the transferable substrate support 224. The first separable contact terminals 214 and the second separable contact terminals 216 are fabricated from molybdenum, tungsten, or a combination thereof in order to reduce total constriction resistance. In one embodiment, which can be combined with other embodiments disclosed herein, the first separable contact terminals 214 and the second separable contact terminals 216 have a surface roughness (Ra) of about 8 microinches (pin) or less, or 4 pin or less.

FIG. 3B illustrates a perspective view of the upper lift section 230 of the lift assembly 220 according to one or more embodiments. In one embodiment, which can be combined with embodiments disclosed herein, the upper lift section 230 is a pedestal. The upper lift section 230 includes one or more second separable contact pins 219 disposed thereon. FIG. 3C illustrates a perspective view of the transport arm 211 of the central transfer device 145 according to one or more embodiments. In one embodiment, which can be combined with other embodiments disclosed herein, the transport arm 211 includes first separable contact pins 221 disposed thereon. Each pin of the first separable contact pins 221 and the second separable contact pins 219 is configured to detachably connect and disconnect with a corresponding terminal of the first separable contact terminals 214 or the second separable contact terminals 216. In one or more embodiments, which can be combined with other embodiments disclosed herein, the first separable contact pins 221 and/or the second separable contact pins 219 are spring-loaded. In one or more embodiments, which can be combined with other embodiments disclosed herein, the first separable contact pins 221 and/or the second separable contact pins 219 are convex.

The first separable contact pins 221 and the second separable contact pins 219 may be fabricated from any suitable material, for example molybdenum, tungsten, or a combination thereof in order to reduce total constriction resistance. In one or more embodiments, the first separable contact pins 221 and the second separable contact pins 219 are fabricated from different materials than the first separable contact terminals 214 and the second separable contact terminals 216. For example, in one embodiment, the first separable contact terminals 214 are fabricated from tungsten, and the second separable contact pins 219 are fabricated from molybdenum. It is believed that the use of different materials as opposing electrical contacting parts, such as the first separable contact terminals 214 and the second separable contact pins 219 can greatly improve the electrical connection reliability between high repetition intermittently contacting parts that are positioned in a vacuum environment, where sliding contact surfaces are undesirable due to particle generation concerns, and use of volatile lubricants materials are not allowed for contamination reasons. In one or more embodiments, the first separable contact pins 221 and/or the second separable contact pins 219 are fabricated from the same material as the first separable contact terminals 214 and the second separable contact terminals 216. In one embodiment, which can be combined with other embodiments disclosed herein, the first separable contact pins 221 and the second separable contact pins 219 have a surface roughness (Ra) of about 8 μin or less, or 4 μin or less.

The connection between the first separable contact pins 221 and the second separable contact pins 219 and the first separable contact terminals 214 and second separable contact terminals 216 due to the shape of one or more of these elements allow the transferable substrate support 224 to self-align with the pedestals, e.g., the upper lift section 230 and/or the transport arm 211. The detachable connection region of each of the first separable contact terminals 214 and second separable contact terminals 216 is configured to detachably connect and disconnect with a corresponding pin of the first separable contact pins 221 and/or the second separable contact pins 219 by repositioning the supporting pedestal (e.g., the upper lift section 230 and/or the transport arm 211) relative to the transferable substrate support 224 in a first direction.

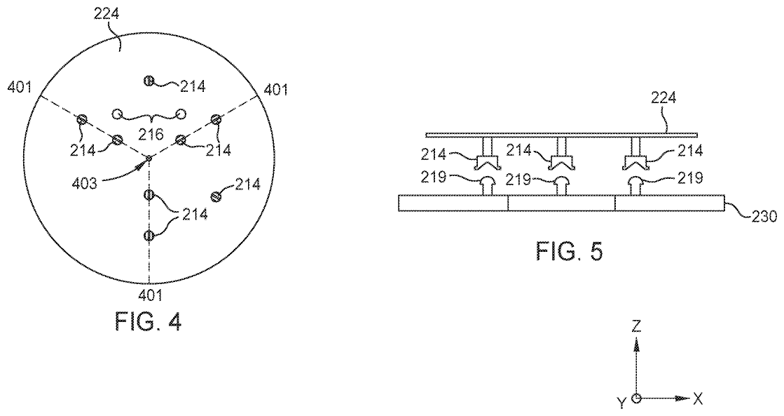

FIG. 4 illustrates a top view of the transferable substrate support 224 of FIG. 3A. FIG. 4 illustrates the orientation of the first separable contact terminals 214 and the second separable contact terminals 216 relative to the transferable substrate support 224. The corresponding v-groove of each of the first separable contact terminals 214 is oriented radially with regard to the transferable substrate support 224. The radial orientation of the v-groove formed on each of the first separable contact terminals 214 allows the coupling between v-grooves and their corresponding pin to not be over-constrained, and thus allows the position of the v-grooves to remain in contact with their corresponding pin while the environment, pedestal, and/or substrate support is heated and/or cooled.

In one embodiment, which can be combined with other embodiments disclosed herein, the first separable contact terminals 214 are disposed on each of three radii 401 intersecting a center point 403 of the substrate support 224. Each radius of the three radii 401 is disposed at an angle, such as an angle of about 120 degrees, with respect to each of the other radii. Thus, in some configurations, the three radii 401 are equidistant from one another. In one embodiment, which can be combined with other embodiments disclosed herein, two terminals of the first separable contact terminals 214 are disposed on each radius of the three radii 401. In one embodiment, which can be combined with other embodiments disclosed herein, two terminals of the first separable contact terminals 214 are disposed at locations on the transferable substrate support 224 other than on the three radii 401 in order to align with the first separable contact pins 221 on the transport arm 211. The second separable contact terminals 216 are located at locations on the transferable substrate support 224 other than on the three radii 401. In one embodiment, which can be combined with other embodiments disclosed herein, the second separable contact terminals 216 includes two terminals.

FIG. 5 illustrates a side view of the orientation of the second separable contact pins 219 relative to the first separable contact terminals 214 that are distributed in an array in the X-Y plane. As described above, the detachable connection region of each of the first separable contact terminals 214 and second separable contact terminals 216 disposed on the transferable substrate support 224 is configured to detachably connect and disconnect with a corresponding pin of the first separable contact pins 221 and/or second separable contact pins 219 disposed on the pedestals, e.g., the upper lift section 230 and/or the transport arm 211.

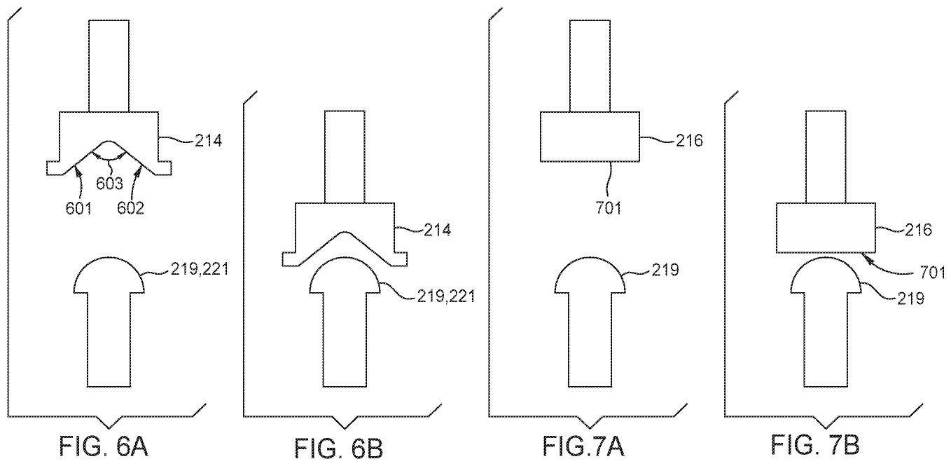

FIGS. 6A and 6B illustrate a detail view of the alignment of the first separable contact pins 221 and/or second separable contact pins 219 with the first separable contact terminals 214 of FIG. 5. FIGS. 6A and 6B, taken in series, illustrate the approach of the second separable contact pins 219 relative to the first separable contact pins 221 as a transferable substrate support 224 is moved relative to the central transfer device 145 in a vertical direction. In one embodiment, which can be combined with other embodiments disclosed herein, one or more of the first separable contact terminals 214 are concave. In one embodiment, each of the first separable contact terminals 214 includes one or more contact surfaces, such as a first surface 601 and a second surface 602 defining a v-groove therebetween. In one embodiment, an angle 603 between the first surface 601 and the second surface 602 is any suitable angle to form the v-groove, for example less than or equal to 60 degrees, for example less than or equal to 30 degrees, for example between about 15 degrees to about 30 degrees. In some embodiments, the first separable contact pins 221 and/or second separable contact pins 219 have a hemispherical contacting surface that is configured to contact at least the first surface 601 or the second surface 602 of the separable contact terminals 214 when they are engaged.

FIGS. 7A and 7B illustrate a detail view of the alignment of the second separable contact pins 219 with the second separable contact terminals 216 according to another embodiment. FIGS. 7A and 7B, taken in series, illustrate the approach of the second separable contact pins 219 relative to the second separable contact terminals 216 as an upper lift section 230 is moved relative to a transferable substrate support 224 in a vertical direction. FIGS. 7A and 7B depict an embodiment in which the second separable contact terminals 216 include a flat surface 701 oriented parallel to the surface 212 of the transferable substrate support 224. In some embodiments, the first separable contact terminals 216 and/or second separable contact pins 219 have a hemispherical contacting surface that is configured to contact at least the flat surface 602 of the separable contact terminals 214 when they are engaged.

In one embodiment, one or more of the separable contact terminals 214 include a contacting surface that includes a v-groove shape, and one or more of the separable contact terminals 216 include a contacting surface that includes a v-groove shape. In another embodiment, one or more of the separable contact terminals 214 include a contacting surface that includes a flat shape, and one or more of the separable contact terminals 216 include a contacting surface that includes a flat shape. In another embodiment, one or more of the separable contact terminals 214 include a contacting surface that includes a v-groove shape, one or more of the other separable contact terminals 214 include a contacting surface that includes a flat shape, one or more of the separable contact terminals 216 include a contacting surface that includes a v-groove shape, and one or more of the other separable contact terminals 216 include a contacting surface that includes a flat shape. In either of these embodiments, the first separable contact pins 221 and/or second separable contact pins 219 have a domed, hemispherical, or other similar shape. In some configurations, it may be desirable to switch the shape of the contacting surfaces of the first and second separable contact terminals 214, 216 with the first and second separable contact pins 221, 219. In one example, the first separable contact terminals 214 has a hemispherical shape and the first separable contact pins 221 have a v-groove shape, and the second separable contact terminals 216 has a hemispherical shape and the second separable contact pins 219 have a flat shape.

In summation, embodiments described herein provide a substrate support assembly and pedestal, which include corresponding separable contact terminals and pins for self-aligning the substrate support on the pedestal while providing an electrical contact. This assembly improves alignment of the substrate support during processing as well as efficiency of processing operations. Furthermore, the shapes of the separable contact terminals and pins are capable of passing high voltage and high current at high processing temperatures in a vacuum environment.

While the foregoing is directed to particular embodiments of the present disclosure, other and further embodiments of the disclosure may be devised without departing from the basic scope thereof, and the scope thereof is determined by the claims that follow.

What is claimed is:

1. A substrate support assembly, comprising:
a transferable substrate support comprising one or more first separable contact terminals disposed on a surface of the transferable substrate support, wherein:
each of the first separable contact terminals comprises a detachable connection region and an electrical connection region, and
the electrical connection region is coupled to an electrical element disposed within the transferable substrate support; and
wherein the detachable connection region of each of the one or more first separable contact terminals is configured to detachably connect and disconnect with a corresponding pin of one or more pins of a supporting pedestal by repositioning the supporting pedestal relative to the transferable substrate support in a first direction.

2. The substrate support assembly of claim 1, wherein one or more of the one or more first separable contact terminals are concave.

3. The substrate support assembly of claim 1, wherein one or more of the one or more first separable contact terminals comprise a flat surface, wherein the first direction is perpendicular to the flat surface.

4. The substrate support assembly of claim 1, wherein the one or more pins are convex.

5. The substrate support assembly of claim 2, wherein each of the one or more first separable contact terminals comprises a first surface and a second surface defining a v-groove therebetween.

6. The substrate support assembly of claim 1, wherein the electrical connection region is operable in a vacuum environment of about 10⁻⁵ to about 10⁻⁸ Torr, at a temperature of about 450° C. to about 550° C., at a current of about 20 A to about 30 A, and at a voltage of about 1000 VDC to about 1500 VDC.

7. The substrate support assembly of claim 1, wherein the surface roughness of the one or more pins and/or the one or more terminals is about 8 microinches (pin) or less.

8. The one or more pins of claim 1, wherein the one or more pins and the one or more terminals comprise molybdenum, tungsten, or a combination thereof.

9. An assembly, comprising:
a transferable substrate support;
one or more first separable contact terminals disposed on a surface of the transferable substrate support;
a supporting pedestal; and
one or more pins disposed on the supporting pedestal, wherein each of the one or more pins is configured to detachably connect and disconnect with a corresponding terminal of the one or more first separable contact terminals.

10. The assembly of claim 9, wherein each of the first separable contact terminals comprises a detachable connection region and an electrical connection region, and the electrical connection region is coupled to an electrical element disposed within the transferable substrate support.

11. The assembly of claim 9, wherein each of the one or more of the first separable contact terminals comprises a flat surface oriented parallel to the transferable substrate support.

12. The assembly of claim 9, wherein each of the one or more first separable contact terminals comprises a first surface and a second surface defining a v-groove therebetween.

13. The assembly of claim 9, wherein the one or more first separable contact terminals and the one or more pins comprise molybdenum, tungsten, or a combination thereof.

14. The assembly of claim 13, wherein the one or more pins comprise a different material than the one or more first separable contact terminals.

15. The assembly of claim 13, wherein the one or more pins comprise the same material as the one or more first separable contact terminals.

16. A transferable substrate support, comprising:
a plurality of separable contact terminals disposed on a surface of the transferable substrate support, the plurality of separable contact terminals comprising:
two first separable contact terminals located on each of three radii, wherein the three radii intersect a center point of the transferable substrate support, each radius being disposed at an angle with respect to each of the other radii; and
one or more second separable contact terminals located at locations on the transferable substrate support other than on the three radii.

17. The transferable substrate support of claim 16, wherein each of the first separable contact terminals comprises a detachable connection region and an electrical connection region, and the electrical connection region is coupled to an electrical element disposed within the transferable substrate support.

18. The transferable substrate support of claim 16, wherein each of the first separable contact terminals comprises a first surface and a second surface defining a v-groove therebetween.

19. The transferable substrate support of claim 16, wherein each of the one or more second separable contact terminals comprises a flat surface oriented parallel to the surface of the transferable substrate support.

20. The transferable substrate support of claim 16, wherein the plurality of separable contact terminals comprise molybdenum, tungsten, or a combination thereof.
